(19) United States
(12) Patent Application Publication
(10) Pub. No.: US 2011/0120544 A1
(43) Pub. Date: May 26, 2011

(54) DEPOSITION INHIBITOR COMPOSITION AND METHOD OF USE

(76) Inventors: David H. Levy, Rochester, NY (US); Gregory L. Zwadlo, River Falls, WI (US)

(21) Appl. No.: 12/622,660

(22) Filed: Nov. 20, 2009

(51) Int. Cl. H01L 31/0216; C23C 16/44; B05D 5/00

(52) U.S. Cl. 136/256; 427/248.1; 427/256; 106/287.26; 257/E31.119

(57) ABSTRACT

A deposition inhibitor composition includes two compatible solvents. The first solvent has a vapor pressure of at least 10 mm Hg at room temperature and the second solvent has a vapor pressure of less than that of the first solvent. The composition further includes a hydrophilic deposition inhibitor material that is dissolved in the composition. This material is soluble in an aqueous solution that comprises at least 50% by weight of water and has a free acid content of less than 2.5 meq/g. This composition is useful to provide a deposition inhibitor pattern for chemical vapor deposition methods such as an atomic-layer-deposition method for forming a patterned thin film includes applying a hydrophilic deposition inhibitor material to a substrate.

### COPENDING AND COMMONLY ASSIGNED APPLICATIONS

Reference is made to the following copending and commonly assigned U.S. patent applications, filed on even date herewith:

U.S. Ser. No. 12/______ filed by myself and entitled “METHOD FOR SELECTIVE DEPOSITION AND DEVICES” (Attorney Docket 95839/JLT);

U.S. Ser. No. 12/______ filed by myself and entitled “METHOD FOR SELECTIVE DEPOSITION AND DEVICES” (Attorney Docket 95835/JLT);

U.S. Ser. No. 12/______ filed by myself and entitled “METHOD FOR SELECTIVE DEPOSITION AND DEVICES” (Attorney Docket 95837/JLT);

U.S. Ser. No. 12/______ filed by myself and entitled “METHOD FOR SELECTIVE DEPOSITION AND DEVICES” (Attorney Docket 95838/JLT); and

U.S. Ser. No. 12/______ filed by myself and Lee W. Tutt and entitled “METHOD FOR SELECTIVE DEPOSITION AND DEVICES” (Attorney Docket 95840/JLT).

### FIELD OF THE INVENTION

This invention relates to a deposition inhibitor composition comprising two compatible solvents. The invention also relates to deposition methods for forming a patterned thin film, and to electronic devices made using these methods.

### BACKGROUND OF THE INVENTION

Modern-day electronics require multiple patterned layers of electrically or optically active materials, sometimes over a relatively large substrate. Electronics such radio frequency identification (RFID) tags, photovoltaics, and optical and chemical sensors all require some level of patterning in their electronic circuitry. Flat panel displays, such as liquid crystal displays or electroluminescent displays rely upon accurately patterned sequential layers to form thin film components of the backplane. These components include capacitors, transistors, and power buses. The industry is continually looking for new methods of materials deposition and layer patterning for both performance gains and cost reductions.

Thin film transistors (TFTs) may be viewed as representative of the electronic and manufacturing issues for many thin film components. TFTs are widely used as switching elements in electronics, for example, in active-matrix liquid-crystal displays, smart cards, and a variety of other electronic devices and components thereof. The thin film transistor (TFT) is an example of a field effect transistor (FET). The best-known example of an FET is the MOSFET (Metal-Oxide-Semiconductor-FET), today's conventional switching element for high-speed applications. For applications in which a transistor needs to be applied to a substrate, a thin film transistor is typically used. A critical step in fabricating the thin film transistor involves the deposition of a semiconductor onto the substrate. Presently, most thin film devices are made using vacuum deposited amorphous silicon as the semiconductor, which is patterned using traditional photolithographic methods. Amorphous silicon as a semiconductor for use in TFTs still has its drawbacks. Thus, there has been active work to find a suitable replacement.

There is a growing interest in depositing thin film semiconductors on plastic or flexible substrates, particularly because these supports would be more mechanically robust, lighter weight, and allow more economic manufacturing, for example, by allowing roll-to-roll processing. A useful example of a flexible substrate is polyethylene terephthalate. Such plastics, however, limit device processing to below 200° C.

In spite of the potential advantages of flexible substrates, there are many problems associated with plastic supports when using traditional photolithography during conventional manufacturing, making it difficult to perform alignments of transistor components across typical substrate widths up to one meter or more. Traditional photolithographic processes and equipment may be seriously impacted by the substrate's maximum process temperature, solvent resistance, dimensional stability, water, and solvent swelling, all key parameters in which plastic supports are typically inferior to glass.

There is interest in utilizing lower cost processes for deposition that do not involve the expense associated with vacuum processing and patterning with photolithography. In typical vacuum processing, a large metal chamber and sophisticated vacuum pumping systems are required in order to provide the necessary environment. In typical photolithographic systems, much of the material deposited in the vacuum chamber is removed. The deposition and photolithography items have high capital costs and preclude the easy use of continuous web based systems.

In the past decade, various materials have received attention as a potential alternative to amorphous silicon for use in semiconductor channels of thin film transistors. The discovery of practical inorganic semiconductors as a replacement for current silicon-based technologies has also been the subject of considerable research efforts. For example, metal oxide semiconductors are known that constitute zinc oxide, indium oxide, gallium indium zinc oxide, tin oxide, or cadmium oxide deposited with or without additional doping elements including metals such as aluminum. Such semiconductor materials, which are transparent, can have an additional advantage for certain applications, as discussed below. Additionally, metal oxide dielectrics such as alumina (Al₂O₃) and TiO₂ are useful in practical electronics applications as well as optical applications such as interference filters.

In addition, metal oxide materials can serve as barrier or encapsulation elements in various electronic devices. These materials also require patterning so that a connection can be made to the encapsulated devices.

Although successful thin films in electronic devices have been made with sputtering techniques, it is clear that very precise control over the reactive gas composition (such as oxygen content) is required to produce good quality devices. Chemical vapor deposition (CVD) techniques, in which two reactive gasses are mixed to form the desired film material at a surface, can be useful routes to achieving high quality film growth. Atomic layer deposition (“ALD”) is yet an alternative film deposition technology that can provide improved thickness resolution and conformal capabilities, compared to its CVD predecessor. The ALD process segments the conventional thin-film deposition process of conventional CVD into single atomic-layer deposition steps.

ALD can be used as a fabrication step for forming a number of types of thin-film electronic devices, including semiconductor devices and supporting electronic components such as resistors and capacitors, insulators, bus lines, and other conductive structures. ALD is particularly suited for forming thin layers of metal oxides in the components of electronic devices. General classes of functional materials that can be deposited with ALD include conductors, dielectrics or insulators, and semiconductors. Examples of useful semiconducting materials are compound semiconductors such as gallium arsenide, gallium nitride, cadmium sulfide, zinc oxide, and zinc sulfide. Advantageously, ALD steps are self-terminating and can deposit precisely one atomic layer when conducted up to or beyond self-termination exposure times. An atomic layer typically ranges from about 0.1 to about 0.5 molecular monolayers with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the complete absence of the other precursor or precursors of the reaction. In practice in any process it is difficult to avoid some direct reaction of the different precursors leading to a small amount of chemical vapor deposition reaction. The goal of any process claiming to perform ALD is to obtain device performance and attributes commensurate with an ALD process while recognizing that a small amount of gas phase nucleation can be tolerated.

There is growing interest in combining ALD with a technology known as selective area deposition (or “SAD”) in which a material is deposited only in those areas that are desired or selected. Sinha et al. [J. Vac. Sci. Technol. B 24 6 2523-2532 (2006)] have remarked that selective area ALD requires that designated areas of a surface be masked or “protected” to prevent ALD reactions in those selected areas, thus ensuring that the ALD film nucleates and grows only on the desired unmasked regions. The masking or protecting agents can be referred to as growth inhibitors.

A particularly advantageous method to leverage SAD is to use commercially viable printing methods to apply growth inhibitors to regions of a substrate. Hydrophilic inhibiting materials, such as those described in the copending and commonly assigned applications described above can be formulated into inhibitor inks and printed onto substrates. After printing the growth inhibitors, ALD growth onto the resulting substrate will form ALD functional films only in areas that do not have a growth inhibitor. In this manner, cost effective printing can be used to produce a final patterned layer of functional material.

Patterning of printed electronic materials has been carried out using a number of “printing” or deposition techniques. For example, some printing techniques utilize high viscosity flowable liquids. Screen-printing, for example, uses flowable compositions with high viscosity. At the other extreme, low viscosity compositions can be deposited by methods such as ink jet printing.

For example, U.S. Patent Application Publication 2006/0001726 (Kodas et al.) describes liquid compositions having a low vapor pressure solvent that can be used using ink jet heads, syringes, or other tools to prevent problems from clogging.

Metallic colloidal solutions containing water and a water-soluble organic solvent are described for various printing and ink jet methods in U.S. Pat. No. 7,445,731 (Okada).

The patterning of the functional materials described in the noted patent may be considered as direct printing of a functional material in the sense that the functional material itself is applied by the printing operation. While this method appears to be straightforward, it requires the availability of soluble functional materials and it requires the ability to print layers at a thickness and thickness uniformity that is required for good device operation.

On the other hand, SAD involves indirect patterning of the functional materials in that the printing operation applies an inhibitor that can be chosen from a broad range of useful inhibitors and can be applied at a broad range of thickness. The functional material results where the inhibitor is not located and its thickness and material performance can be optimized independently of the inhibitor application.

In an optimal operation, very thin layers of inhibitor can be used. This has the advantage of low utilization of inhibitor chemicals, easy removal, if desired, of the inhibitors after the ALD process and potential improvements in patterning resolution. However, it is difficult to “print” very low levels of inhibitors to provide thin layers. Thus, methods are required to permit the convenient printing of hydrophilic inhibitor formulations with low coverage.

### SUMMARY OF THE INVENTION

This invention provides a deposition inhibitor composition comprising first and second compatible solvents, the first solvent having a vapor pressure of at least 10 mm Hg at room temperature and the second solvent having a vapor pressure of less than that of the first solvent,

the composition further comprising a hydrophilic deposition inhibitor material that is dissolved in the composition, that is soluble in an aqueous solution that comprises at least 50% by weight of water, and that has a free acid content of less than 2.5 meq/g.

This invention also provides a deposition method for forming a patterned thin film comprising:

A) applying the composition of this invention comprising a deposition inhibitor material to a substrate,

B) simultaneously or subsequently to step A), patterning the deposition inhibitor material to provide selected areas on the substrate where the deposition inhibitor material is absent, and

C) depositing an inorganic thin film on the substrate by chemical vapor deposition only in those areas where the deposition inhibitor material is absent.

Further, this invention provides a method of treating a substrate comprising:

A) providing the deposition inhibitor composition of this invention to an application device, and

B) applying the deposition inhibitor composition to a substrate after at least 70% of the first solvent has evaporated.

The present invention provides an advantage in that compositions comprising hydrophilic deposition inhibitor polymers can be provided on substrates in a uniform manner with relatively low coverage. That is, thinner uniform or patterned layers can be applied. This is achieved by using the invention composition containing two different solvents for which vapor pressure of a first solvent is at least 5 times the vapor pressure of a second solvent. Due to this vapor pressure different, an ink (composition) can be formulated so that at a specific point in the printing process, the first solvent can be substantially removed while retaining most of the second solvent, thus concentrating the composition with the hydrophilic deposition inhibitor material (“ink”) in a controlled fashion.

For example, after the deposition inhibitor composition of the invention is applied to a suitable application device (such as a printing plate) in a patterned manner, at least 70% of the high vapor pressure first solvent is evaporated, leaving a very thin layer on the application device consisting essentially of the hydrophilic deposition inhibitor material (for example, hydrophilic polymer) dissolved in the low vapor pressure second solvent. This thin layer is then applied to a device substrate, and the remaining solvent is then removed, leaving a very thin, patterned layer on that substrate.

Alternatively, the deposition inhibitor composition (ink formulation) is applied uniformly to an intermediate substrate. At this point, at least 70% of the high vapor pressure first solvent has been evaporated, leaving a very thin layer on the intermediate substrate consisting essentially of the hydrophilic deposition inhibitor material (hydrophilic polymer) dissolved in the low vapor pressure second solvent. A suitable application device (such as a printing plate) can be contacted to the intermediate substrate in order to transfer the concentrated composition (“ink”) layer. This thin layer on the application device is then applied to a substrate and the remaining second solvent is then removed, leaving a very thin, patterned layer on the substrate.

After either of the described processes, the resulting substrate can then be treated with an ALD deposition. The presence of the patterned hydrophilic deposition inhibitor material will yield ALD functional film growth only in regions that do not contain the hydrophilic deposition inhibitor material.

Other objects, features, and advantages of the present invention will become apparent to those skilled in the art upon a reading of the following detailed description when taken in conjunction with the drawings that show and describe illustrative embodiments of the invention.

### BRIEF DESCRIPTION OF THE DRAWINGS

FIG. 1 is a cross-sectional side view of a delivery head for atomic layer deposition for one embodiment of the present invention.

FIG. 2 is a flow chart describing one embodiment of the steps of the present invention.

FIG. 3 is a flow chart describing the steps for an ALD process for use in the present invention.

FIG. 4 is a cross-sectional side view of one embodiment of a deposition device for atomic layer deposition that can be used in the present process.

FIG. 5 is a cross-sectional side view of an embodiment, for one exemplary system of gaseous materials, of the distribution of gaseous materials to a substrate that is subject to thin film deposition;

FIGS. 6A and 6B are cross-sectional side views of one embodiment of the distribution of a system of gaseous materials, schematically showing the accompanying deposition operation;

FIG. 7 is a perspective view, from the output face side, of a portion of one embodiment of a deposition device, showing the orientation of output channels relative to the substrate and reciprocating motion, showing one exemplary arrangement of gas flow in the deposition device;

FIGS. 8A and 8B are cross-sectional views taken orthogonally to the cross-sectional views of previous FIGS. 4, 5, 6A, and 6B, showing gas flow directions for output channels in various embodiments.

FIG. 9 is a schematic diagram showing an alternative motion pattern for reciprocating and orthogonal movement.

FIG. 10 is a block diagram for one embodiment of a deposition system that uses the method according to the present invention.

FIG. 11 is a block diagram showing another embodiment of deposition system applied to a moving web in accordance with the present invention, with the deposition device being kept stationary.

FIGS. 12A through 12E show the layers on the substrate at different points in the process in one embodiment of the present invention.

FIGS. 13A through 13D show the layers on the substrate at different points in another embodiment of the present invention.

### DETAILED DESCRIPTION OF THE INVENTION

### Definitions

As used herein, the term “hydrophilic polymer” refers to a naturally occurring or synthetically prepared organic compound having a molecular weight of at least 1,000. This organic compound is soluble in an aqueous solution comprising 50% water and the rest comprising one or more water-miscible organic solvents for example alcohols (such as methanol, ethanol, n-propanol, 2-propanol, t-butyl alcohol, glycerin, dipropylene glycol, ethylene glycol, and polypropylene glycol), ketones (such as acetone and methyl ethyl ketone), glycol ethers (such as ethylene glycol monomethyl ether, ethylene glycol monoethyl ether, ethylene glycol monobutyl ether, diethylene glycol monoethyl ether, diethylene glycol monobutyl ether, diethylene glycol diethyl ether, triethylene glycol monobutyl ether, and dipropylene glycol monomethyl ether), and water-soluble nitrogen-containing organic solvents (such as 2-pyrrolidone and N-methyl pyrrolidone), and ethyl acetate.

For example, the hydrophilic polymer satisfies both of the following tests:

a) it is soluble to at least 1% by weight in a solution containing at least 50 weight % water as measured at 40° C., and

b) it provides an inhibition power of at least 200 Å to deposition of zinc oxide by an ALD process.

The term “deposition inhibitor material” refers herein to a material applied to the substrate as well as the material resulting from any optionally subsequent crosslinking or other reaction that modifies the material that may occur prior to depositing an inorganic thin film on the substrate using a chemical vapor deposition technique.

For the description that follows, the term “gas” or “gaseous material” is used in a broad sense to encompass any of a range of vaporized or gaseous elements, compounds, or materials. Other terms used herein, such as: reactant, precursor, vacuum, and inert gas, for example, all have their conventional meanings as would be well understood by those skilled in the materials deposition art. The FIGS. provided with this application are not drawn to scale but are intended to show overall function and the structural arrangement of some embodiments of the present invention.

### Deposition Inhibitor Composition

The composition of this invention contains at least two solvents (“first” and “second” solvents) that have different vapor pressures. The two “different” solvents may actually be two different mixtures of solvents as long as the cumulative vapor pressures of the two mixtures are different.

For example, the second solvent can have a vapor pressure that is less than ⅕^{th} of the vapor pressure of the first solvent. More particularly, the second solvent can have a vapor pressure that is less than 1/10^{th} of the vapor pressure of the first solvent. The first solvent (or mixture) can have a vapor pressure of at least 10 mm Hg at room temperature (for example 20° C.). The vapor pressure of the second solvent can be from about 1 to about 1000 mmHg at a given temperature of use. The difference in vapor pressures between the first and second solvents is at least 8 mm Hg and typically at least 20 mm Hg at a given temperature. As one skilled in the art would readily understand from this teaching, the vapor pressure of the second solvent must be such that it does not substantially evaporate before the first solvent or before the composition of this invention is applied to a suitable application device or intermediate substrate while the first solvent can be vaporized quickly at room temperature.

It is also useful that the second solvent is soluble in the first solvent at greater than 40% by weight, or at least the second solvent is miscible with the first solvent.

In addition, the first and second solvents can have a molecular weight independently of less than 200 g/mol, or less than 150 g/mol in many embodiments.

Representative useful first solvents include but are not limited to, isopropyl alcohol, water, methanol, ethanol, and acetone, or mixtures of two or more of these solvents.

Useful second solvents are polyols, including polyols having one or more carboxy groups. Representative second solvents include but are not limited to, glycerol, 1,3-butanediol, 2,3-butanediol, ethylene glycol, propylene glycol, propanoic acid, and succinic acid, and mixtures of two or more of these solvents.

It may be necessary to adjust certain properties of the deposition inhibitor compositions (ink formulations) by the addition of auxiliary components. Examples of auxiliary or non-essential components include but are not limited to, surfactants, preservatives, humectants, and drying agents. Surfactants can be any compound that is designed to modify the surface tension of the compounds. Surfactants can be small molecules having a molecular weight of less than 500 g/mole, or polymeric surface active agents. Preservatives can be any materials having the effect of lengthening the active life of the deposition inhibitor composition from decomposition or biological contamination. Humectants and drying agents include materials designed to modify the rate and nature of the solvent evaporation from the drying films.

The deposition inhibitor composition includes one or more deposition inhibitor materials as essential components that inhibit the deposition of the thin films on its surface. In this manner, portions of the substrate where there is a deposition inhibitor material will have little to no thin film growth, and in areas of the substrate that are generally free of the deposition inhibitor material will have thin film growth. The amount of deposition inhibitor material in the composition is at least 0.1 weight %, generally from about 0.5 to about 5 weight %, and typically from 0.8 to 2 weight %.

As noted above, useful deposition inhibitor materials include hydrophilic polymers that have a free acid content of less than 2.5 meq/g and that are soluble in an aqueous solution comprises at least 50% of water by weight. Some embodiments have a free acid content of less than or equal to 1.0 meq/l or even less than 0.2 meq/g of polymer. The upper limit can be 2.2 meq/g of polymer. These hydrophilic polymers are generally not crosslinked since that will likely reduce their water-solubility. However, crosslinkable polymers may be useful where crosslinking is performed after application of the polymer. Crosslinking of the polymer may increase its stability especially in applications where the polymer remains in the constructed device.

Some representative hydrophilic polymers are the following classes of materials, but this list is not meant to be limiting the scope of the hydrophilic polymers useful in this invention:

a) Hydrophilic polymers that have in their backbones, side chains, or both backbone and side chains, multiple secondary or tertiary amide groups that are represented by the following acetamide structure>N—C(═O)—. In some embodiments, at least some of the acetamide groups are recurring and form at least part of the hydrophilic polymer backbone through the nitrogen atom. In other embodiments, at least some of the acetamide groups are on side chains of the hydrophilic polymer and are represented by the following structure —N(R)—C(═O)—R′ wherein R is hydrogen or an alkyl, cycloalkyl, or aryl group, and R′ is an alkyl, cycloalkyl, or aryl group. For example, R is hydrogen or a substituted or unsubstituted alkyl having 1 to 4 carbon atoms and R′ is a substituted or unsubstituted alkyl group having 1 to 3 carbon atoms. Examples of such hydrophilic polymers include but are not limited to, poly(vinyl pyrrolidone), poly(N-vinyl acetamide), and poly(2-ethyl-2-oxazoline), or a mixture of two or more of these polymers.

b) Hydrophilic polymers that are neutralized acids having a pKa of 5 or less, wherein at least 90% of the acid groups are neutralized. For example, such hydrophilic polymers can comprise neutralized carboxy, sulfo, phospho, sulfinic, or phosphinic acid groups. Such neutralized groups can be pendant to the polymer backbones. Examples of such hydrophilic polymer include but are not limited to, neutralized homopolymers or copolymers derived from (meth)acrylic acid or styrenesulfonic acid.

c) Hydrophilic poly(vinyl alcohol)s having a degree of hydrolysis of less than 95%, or a degree of hydrolysis of less than 90%, and typically a degree of hydrolysis of at least 50% and less than 85%.

d) Hydrophilic polymers that have in their backbones, side chains, or both backbone and side chains, multiple hydrophilic groups that are represented by the following structure —C—O—C—. In some embodiments, at least some of the hydrophilic groups are ether groups that are recurring and form at least part of the hydrophilic polymer backbone. In other embodiments, at least some of hydrophilic groups are on side chains of the hydrophilic polymer and are represented by the following structure —(O)ₓ-(alkylene-O)— wherein alkylene is substituted or unsubstituted and has 1 to 4 carbon atoms and x is 0 or 1. It is possible for some hydrophilic polymers to have these groups wherein x is 0 and the ether groups are repeating on the side chains and alkylene has 1 to 3 carbon atoms. Examples of such hydrophilic polymers include but are not limited to, poly(methyl vinyl ether), poly(ethylene glycol), polypropylene glycol), and a glycerol propoxylate, or a mixture of two or more of these polymers.

It is to be understood that of the hydrophilic polymers described above, not every hydrophilic polymer in every class may perform optimally, but that a skilled artisan would be able to use routine experimentation to obtain the best hydrophilic polymer for a desired use. It is also to be understood that some hydrophilic polymers of a given class of polymer may not perform as well as hydrophilic polymers in other classes, but that the various hydrophilic polymers can still be shown to provide improvements in specific formulations and uses.

### Deposition Methods

The present invention provides various electronic devices including but not limited to, integrated circuits, active-matrix displays, solar cells, active-matrix imagers, sensors, and rf labels using a suitable chemical vapor deposition method described herein. Such electronic devices have a substrate that can be composed of polymeric films (such as polyethylene terephthalate, polyethylene naphthalate, polyimide, polyetheretherketone (PEEK), or any polymer with suitable temperature resistance for electronics applications), ceramics, glasses, and metal foils including aluminum, steel, or stainless steel.

The production of a patterned functional thin film for the described electronic devices involves a first step of applying the deposition inhibitor composition to a substrate to form the inhibitor pattern, followed by a subsequent step of performing a chemical vapor deposition onto the substrate to form functional materials where the deposition inhibitor material is absent.

As an example of the first step of deposition inhibitor application, after the composition of this invention is applied to a suitable application device (such as a printing plate) in a patterned manner, at least 70% of the high vapor pressure solvent is evaporated (and in most embodiments, almost all or at least 95% is removed), leaving a very thin layer on the application device consisting essentially of the deposition inhibitor material (hydrophilic polymer) dissolved in the low vapor pressure solvent. The high vapor pressure solvent can be removed using any suitable means including but not limited to, air drying, convection oven drying, forced air drying, and inert gas drying. This thin layer is then applied to a device substrate and the remaining solvent is then removed, leaving a completely dried, very thin, patterned layer on the substrate. This removal can be accomplished using the same or different techniques as removal of the high vapor pressure solvent, but in addition, the thin layer may be dried with heated air or a heated surface (for example, platen) to ensure complete removal of the low vapor pressure solvent to essentially complete dryness.

As a second example of the first step of deposition inhibitor application, the composition of this invention can be applied uniformly to an intermediate substrate. At this point, at least 70% of the high vapor pressure solvent is evaporated (as described above), leaving a very thin layer on the intermediate substrate consisting essentially of the hydrophilic deposition inhibitor material (hydrophilic polymer) dissolved in the low vapor pressure solvent. A suitable application device (such as a printing plate) can be contacted with the intermediate substrate in order to transfer the concentrated “ink” layer. This thin layer on the application device is then applied to a substrate, and the remaining solvent is then removed as described above, leaving a very thin patterned layer on the substrate.

The second step of chemical vapor deposition can be performed by any of the methods discussed below to product a patterned layer of functional material. A particularly preferred method of performing the functional material deposition is ALD as described below.

A deposited pattern of a composition that comprises a deposition inhibitor material is applied to the substrate using a suitable donor or application device. A deposited inorganic thin film is deposited only in selected areas of the substrate where the composition comprising a hydrophilic deposition inhibitor material is absent. Useful thin films are described below.

The composition of this invention comprising the deposition inhibitor material can be applied in a patternwise fashion using any conventional printing technology and the corresponding application device. Particularly useful printing technologies are inkjet, flexography, gravure printing, micro-contact printing, offset lithography, patch coating, screen printing, and donor transfer methods. Useful application devices then can be printing plates including lithographic, gravure, and flexographic printing plates, and an inkjet printing device (such as a printer or printing cartridge). The deposition inhibitor may also be applied to a substrate using any of the above methods, or by hopper coating, spin coating blade coating, or dip coating.

For example, one useful technique for formation of a pattern on an application device using to form an elastomeric stamp is described in U.S. Patent Application Publication 2008/0083484 (Blanchet et al.) that is incorporated herein by reference.

After the deposition inhibitor material has been applied to the substrate, a thin film can be applied using a chemical vapor deposition (CVD) method, the general principles of which are described in many publications including Dobkin et al., Principles of Chemical Vapor Deposition, 1 Edition, April 2003 and the Handbook of Chemical Vapor Deposition 2^{nd} Ed., Second Edition: Principles, Technology and Applications (Materials Science and Process Technology Series), Pierson et al., Jan. 14, 2000. Specific types of CVD systems include the use of tube reactions as described in U.S. Pat. No. 6,709,525 (Song), showerhead reactors as described in U.S. Pat. No. 6,284,673 (Dunham), and linear injector reactors as described in U.S. Pat. No. 5,136,975 (Bartholomew et al.), all of which publications are incorporated herein by reference.

While these methods can be used, it is best to carry out the present invention using atomic layer deposition (ALD). ALD processes can be understood from the background section and various publications cited therein. Additional teaching about ALD and useful apparatus for carrying out the process is provided in U.S. Pat. No. 7,105,054 (Lindfors), U.S. Pat. No. 7,085,616 (Chin et al.), U.S. Pat. No. 7,141,095 (Aitchison et al.), and U.S. Pat. No. 6,911,092 (Sneh), all of which are incorporated herein by reference.

The process of making the patterned thin film can be carried out below a maximum substrate temperature of about 600° C., or typically below 250° C., or even at temperatures as low as room temperature (about 25° C.). The temperature selection generally depends on the substrate and processing parameters known in the art. These temperatures are well below traditional integrated circuit and semiconductor processing temperatures, which enables the use of any of a variety of relatively inexpensive substrates, such as flexible polymeric supports.

The method allows one to make thin films employing a system for delivery of gaseous materials to a substrate surface that can be adaptable to deposition on larger and web-based substrates and capable of achieving a highly uniform thin film deposition at improved throughput speeds. This method optionally employs a continuous spatially dependent ALD (as opposed to pulsed or time dependent ALD) gaseous material distribution. The method optionally allows operation at atmospheric or near-atmospheric pressures and is capable of operating in an unsealed or open-air environment. Because of the use of the deposition inhibitor material described above, the thin film is deposited only in selected areas of a substrate.

Atomic layer deposition can be used to deposit a variety of inorganic thin films that are metals or that comprise a metal-containing compound. Such metal-containing compounds include, for example (with respect to the Periodic Table) a Group V or Group VI anion. Such metal-containing compound can include but are not limited to, oxides, nitrides, sulfides or phosphides for example of zinc, aluminum, titanium, hafnium, zirconium, or indium, or combinations of these metals. Useful metals include but are not limited to, copper, tungsten, aluminum, nickel, ruthenium, and rhodium.

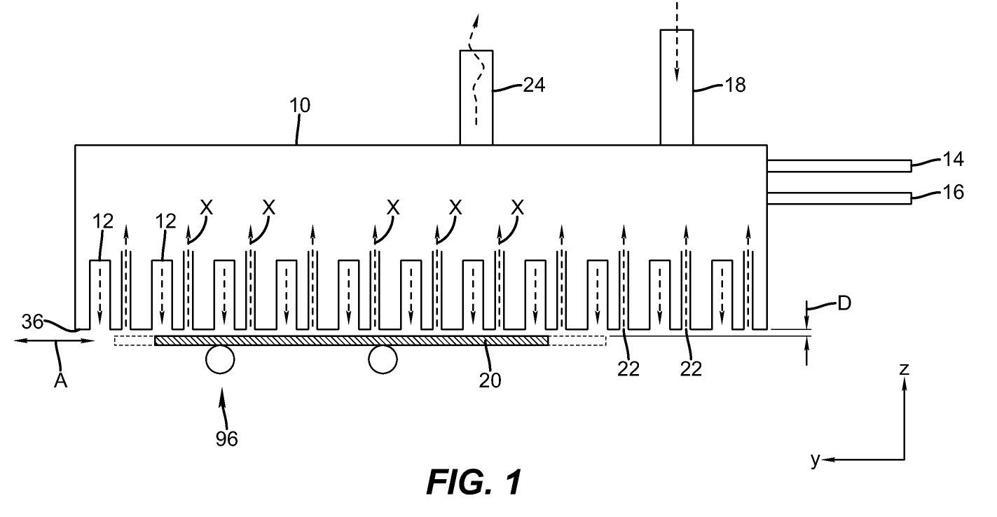

Referring to FIG. 1, a cross-sectional side view of one embodiment of a delivery head 10 for atomic layer deposition onto a substrate 20 according to the present invention is shown. Delivery head 10 has a gas inlet conduit 14 that serves as an inlet port for accepting a first gaseous material, a gas inlet conduit 16 for an inlet port that accepts a second gaseous material, and a gas inlet conduit 18 for an inlet port that accepts a third gaseous material. These gases are emitted at an output face 36 via output channels 12, having a structural arrangement that may include a diffuser, as described subsequently. The dashed line arrows in FIG. 1 refer to the delivery of gases to substrate 20 from delivery head 10. In FIG. 1, dotted line arrows X also indicate paths for gas exhaust (shown directed upwards in this figure) and exhaust channels 22, in communication with an exhaust conduit 24 that provides an exhaust port. Since the exhaust gases may still contain quantities of unreacted precursors, it may be undesirable to allow an exhaust flow predominantly containing one reactive species to mix with one predominantly containing another species. As such, it is recognized that the delivery head 10 may contain several independent exhaust ports.

In one embodiment, gas inlet conduits 14 and 16 are adapted to accept first and second gases that react sequentially on the substrate surface to effect ALD deposition, and gas inlet conduit 18 receives a purge gas that is inert with respect to the first and second gases. Delivery head 10 is spaced a distance D from substrate 20, which may be provided on a substrate support, as described in more detail subsequently. Reciprocating motion can be provided between substrate 20 and delivery head 10, either by movement of substrate 20, by movement of delivery head 10, or by movement of both substrate 20 and delivery head 10. In the particular embodiment shown in FIG. 1, substrate 20 is moved by a substrate support 96 across output face 36 in reciprocating fashion, as indicated by the arrow A and by phantom outlines to the right and left of substrate. It should be noted that reciprocating motion is not always required for thin-film deposition using delivery head 10. Other types of relative motion between substrate 20 and delivery head 10 could also be provided, such as movement of either substrate 20 or delivery head 10, or both, in one or more directions.

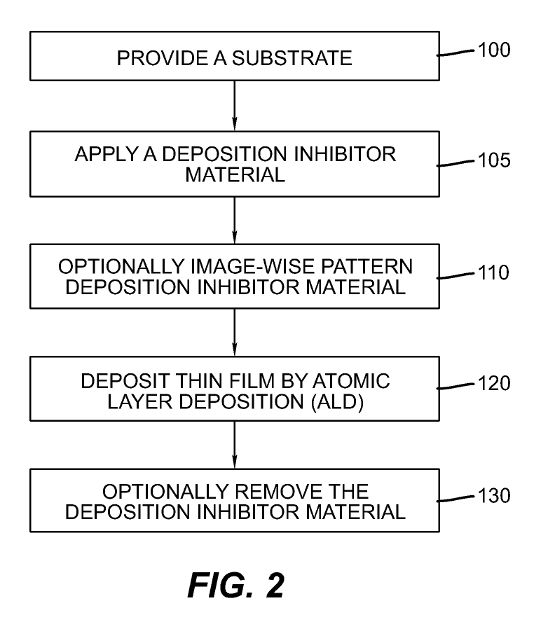

FIG. 2 is a step diagram for one embodiment of a method of the present invention for making a patterned thin film using a combination of selected area deposition (SAD) and ALD. As shown in Step 100, a substrate is supplied into the system. In Step 105, a deposition inhibitor material is deposited. The deposition inhibitor material can generically be any material that causes the material deposition to be inhibited. In one embodiment, the deposition inhibitor material is chosen specifically for the material to be deposited. The deposition of the deposition inhibitor material in Step 105 can be in a patterned manner, such as using inkjet, flexography, gravure printing, microcontact printing, offset lithography, patch coating, screen printing, or donor transfer. In an alternative embodiment, Step 105 can be used to deposit a uniform layer of the deposition inhibitor material and Step 110 can be optionally employed to form a patterned layer of the deposition inhibitor material.

Continuing with FIG. 2, Step 120 deposits the desired thin film, for example, by an Atomic Layer Deposition (ALD) process. Generically this deposition can use any suitable chemical vapor deposition equipment, such as ALD equipment, for example with a spatially dependent ALD system. The thin film is deposited only in the areas of the substrate where there is no deposition inhibitor material. Depending on the use of the thin film, the deposition inhibitor material may remain on the substrate for subsequent processing or may be removed as shown in Step 130 of FIG. 2.

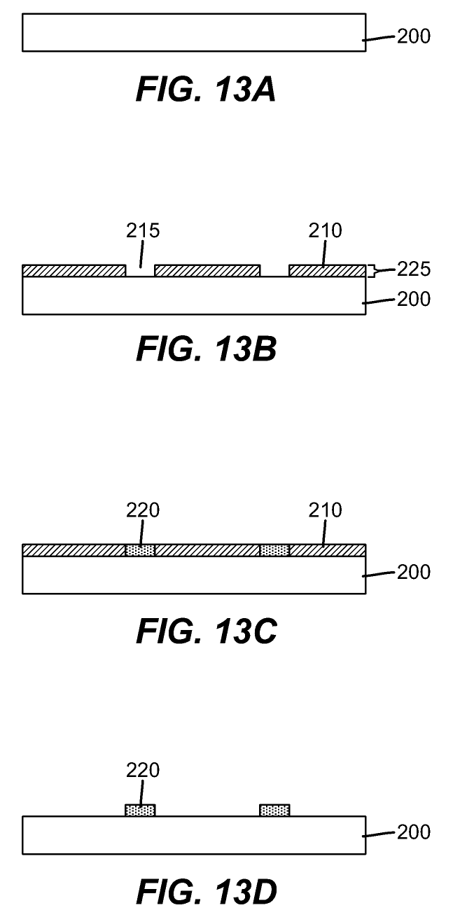

In some embodiments, the deposition inhibitor material is characterized by an inhibition power. Referring to FIG. 13B, the inhibition power is defined as the thickness of a deposited layer that can form in the uninhibited areas 215 before the onset of significant deposition in the inhibited areas 210.

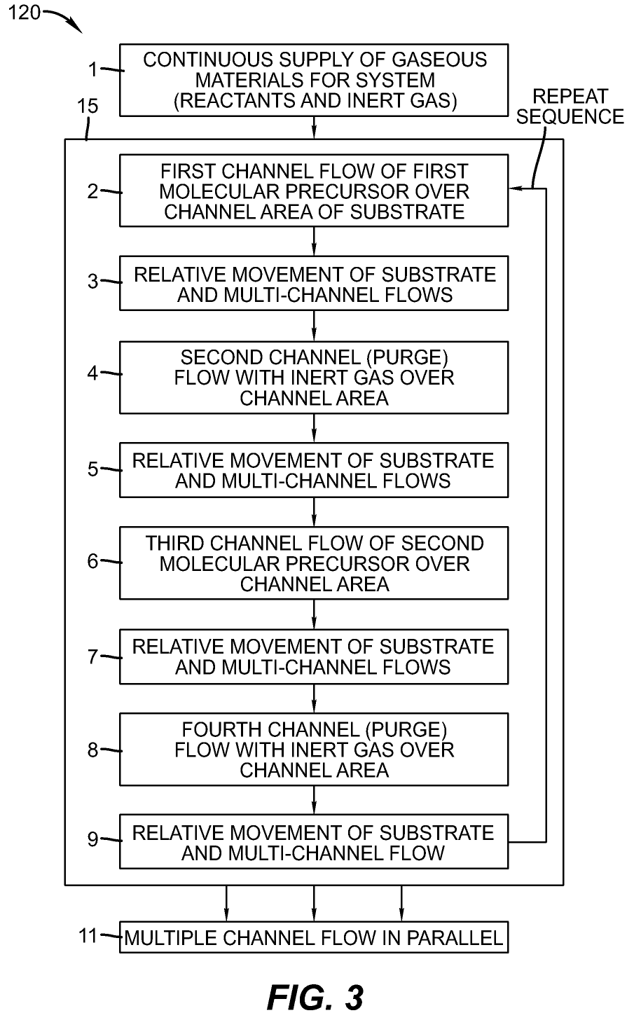

FIG. 3 is a step diagram of a preferred embodiment of an ALD process 120 for making the thin film, in which two reactive gases are used, a first molecular precursor and a second molecular precursor. Gases are supplied from a gas source and can be delivered to the substrate, for example, via a deposition device. Metering and valving apparatus for providing gaseous materials to the deposition device can be used.

As shown in Step 1, a continuous supply of gaseous materials for the process is provided for depositing a thin film of material on a substrate. The Steps in Sequence 15 are sequentially applied. In Step 2, with respect to a given area of the substrate (referred to as the channel area), a first molecular precursor or reactive gaseous material is directed to flow in a first channel over the channel area of the substrate and reacts therewith. In Step 3 relative movement of the substrate and the multi-channel flows in the system occurs, which sets the stage for Step 4, in which second channel (purge) flow with inert gas occurs over the given channel area. Then, in Step 5, relative movement of the substrate and the multi-channel flows sets the stage for Step 6, in which the given channel area is subjected to atomic layer deposition in which a second molecular precursor now over the given channel area of the substrate and reacts with the previous layer on the substrate to produce (theoretically) a monolayer of a desired material. A first molecular precursor is in gas form, for example, an organometallic compound such as diethylzinc or trimethyl-aluminum. In such an embodiment, the second molecular precursor is also in gaseous form and can be, for example, a non-metallic oxidizing compound. The process of deposition can comprise flows of gaseous materials that are orthogonal towards the substrate, transverse across the face of the substrate, or some combination of both types of flows. For example, the channels comprise or are connected to a series of corresponding substantially parallel elongated openings in the output face of at least one delivery head for thin film deposition. More than one delivery head may be employed for deposition of one or more thin films.

In many forms of spatial ALD, the channels are small and in close proximity, with a length dimension in the direction of substrate motion that is less than 2 cm. Alternatively, the channel areas may be large areas of gas exposure as disclosed in U.S. Patent Application Publication 2007/0224348 (Dickey et al.).

In Step 7, relative movement of the substrate and the multi-channel flows then sets the stage for Step 8 in which again an inert gas is used, this time to sweep excess second molecular precursor from the given channel area from the previous Step 6. In Step 9, relative movement of the substrate and the multi-channels occurs again, which sets the stage for a repeat sequence, back to Step 2. The cycle is repeated as many times as is necessary to establish a desired film. In this embodiment of the method, the steps are repeated with respect to a given channel area of the substrate, corresponding to the area covered by a flow channel. Meanwhile the various channels are being supplied with the necessary gaseous materials in Step 1. Simultaneous with the sequence of box 15 in FIG. 1, other adjacent channel areas are being processed, which results in multiple channel flows in parallel, as indicated in overall Step 11. As indicated above, parallel flow can be either substantially orthogonal or substantially parallel to the output face of the deposition device.

The primary purpose of the second molecular precursor is to condition the substrate surface back toward reactivity with the first molecular precursor. The second molecular precursor also provides material from the molecular gas to combine with metal at the surface, forming an oxide with the freshly deposited zinc-containing precursor.

This particular embodiment does not need to use a vacuum purge to remove a molecular precursor after applying it to the substrate. Purge steps are expected by most researchers to be the most significant throughput-limiting step in ALD processes.

Assuming that, for the two reactant gases in FIG. 3, AX and BY are used, for example. When the reaction gas AX flow is supplied and flowed over a given substrate area, atoms of the reaction gas AX are chemically adsorbed onto a substrate, resulting in a layer of A and a surface of ligand X (associative chemisorptions) (Step 2). The remaining reaction gas AX is then purged with an inert gas (Step 4). The flow of reaction gas BY and a chemical reaction between AX (surface) and BY (gas) occur, resulting in a molecular layer of AB on the substrate (dissociative chemisorptions) (Step 6). The remaining gas BY and by-products of the reaction are purged (Step 8). The thickness of the thin film may be increased by repeating the process cycle (steps 2-9) many times.

Because the film can be deposited one monolayer at a time it tends to be conformal and have uniform thickness.

Thin films of oxides that can be made using the method of the present invention include but are not limited to zinc oxide (ZnO), aluminum oxide (Al₂O₃), hafnium oxide, zirconium oxide, indium oxide, tin oxide, and others that would be readily apparent to a skilled worker. Mixed structure oxides that can be made can include but are not limited to InZnO. Doped materials that can be made can include but are not limited to ZnO:Al, MgₓZn₁₋ₓO, and LiZnO.

Thin films of metals that can be made include but are not limited to, copper, tungsten, aluminum, nickel, ruthenium, and rhodium. It will be apparent to the skilled artisan that alloys of two, three, or more metals may be deposited, compounds may be deposited with two, three, or more constituents, and graded films and nano-laminates may be produced as well.

For various volatile zinc-containing precursors, precursor combinations, and reactants useful in ALD thin film processes, reference is made to the Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159.

Although oxide substrates provide groups for ALD deposition, plastic substrates can be also used by suitable surface treatment.

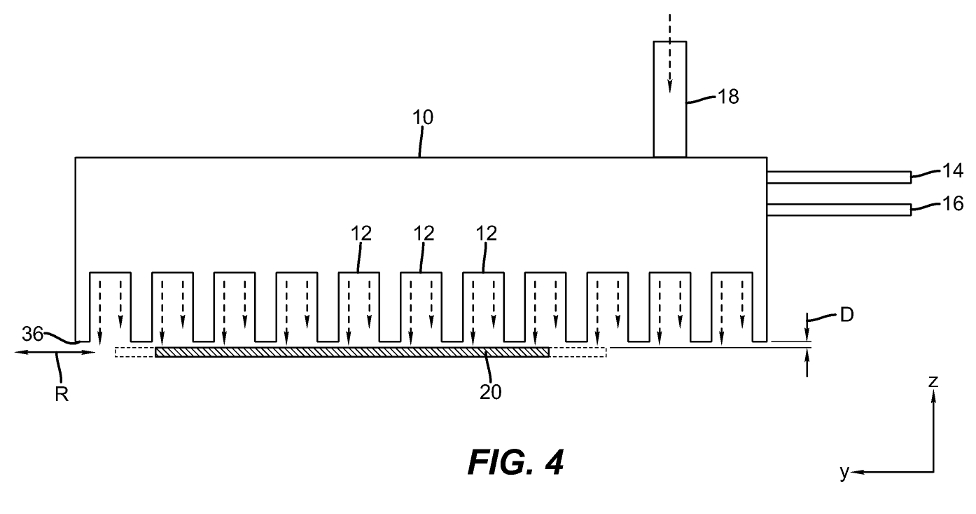

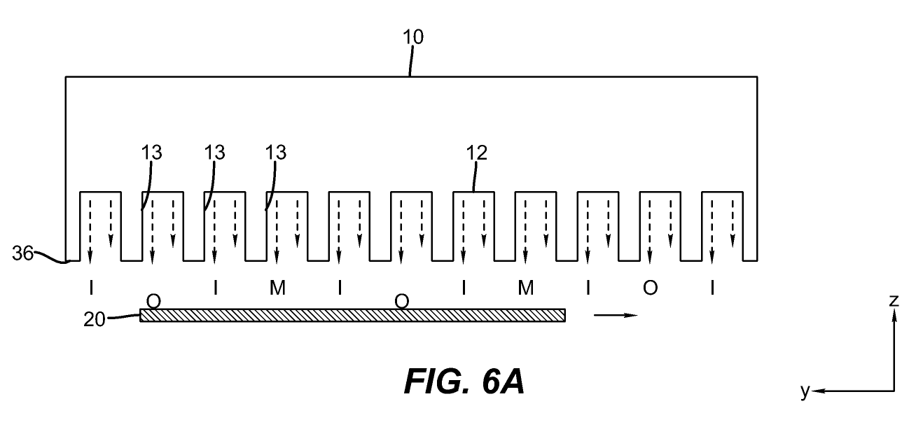

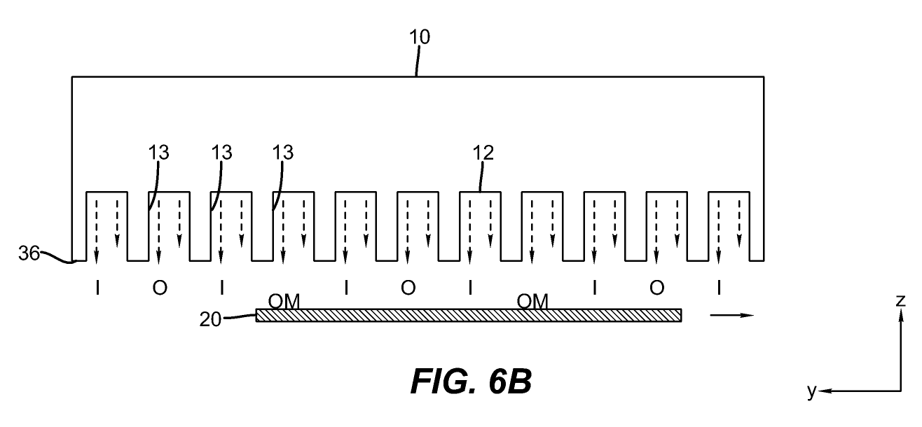

Referring now to FIG. 4, there is shown a cross-sectional side view of one embodiment of a delivery head 10 that can be used for atomic layer deposition onto a substrate 20. Delivery head 10 has a gas inlet port 14 for accepting a first gaseous material, a gas inlet port 16 for accepting a second gaseous material, and a gas inlet port 18 for accepting a third gaseous material. These gases are emitted at an output face 36 via output channels 12, having a structural arrangement described subsequently. The arrows in FIG. 4 and subsequent FIGS. 6A and 6B refer to the diffusive transport of the gaseous material, and not the flow, received from an output channel. In this particular embodiment, the flow is substantially directed out of the page of the figure, as described further below.

In one embodiment, gas inlet ports 14 and 16 are adapted to accept first and second gases that react sequentially on the substrate surface to effect ALD deposition, and gas inlet port 18 receives a purge gas that is inert with respect to the first and second gases. Delivery head 10 is spaced a distance D from substrate 20, provided on a substrate support, as described in more detail subsequently. Reciprocating motion can be provided between substrate 20 and delivery head 10, either by movement of substrate 20, by movement of delivery head 10, or by movement of both substrate 20 and delivery head 10. In the particular embodiment shown in FIG. 4, substrate 20 is moved across output face 36 in reciprocating fashion, as indicated by the arrow R and by phantom outlines to the right and left of substrate 20 in FIG. 4. It should be noted that reciprocating motion is not always required for thin-film deposition using delivery head 10. Other types of relative motion between substrate 20 and delivery head 10 could also be provided, such as movement of either substrate 20 or delivery head 10 in one or more directions, as described in more detail subsequently.

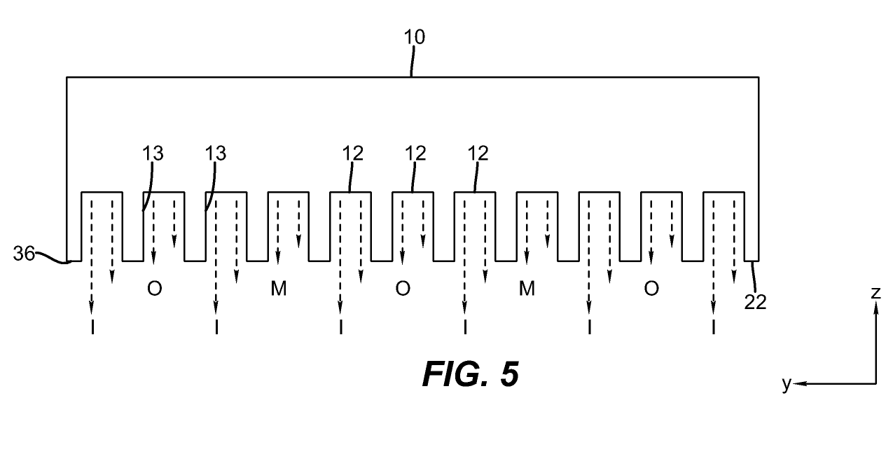

The cross-sectional view of FIG. 5 shows gas flows emitted over a portion of output face 36 of delivery head 10. In this particular arrangement, each output channels 12, separated by partitions 13, is in gaseous flow communication with one of gas inlet ports 14, 16 or 18 seen in FIG. 4. Each output channel 12 delivers typically a first reactant gaseous material O, or a second reactant gaseous material M, or a third inert gaseous material I.

FIG. 5 shows a relatively basic or simple arrangement of gases. It is envisioned that a plurality of non-metal deposition precursors (like material O) or a plurality of metal-containing precursor materials (like material M) may be delivered sequentially at various ports in a thin-film single deposition. Alternately, a mixture of reactant gases, for example, a mixture of metal precursor materials or a mixture of metal and non-metal precursors may be applied at a single output channel when making complex thin film materials, for example, having alternate layers of metals or having lesser amounts of dopants admixed in a metal oxide material. The inter-stream labeled I separates any reactant channels in which the gases are likely to react with each other. First and second reactant gaseous materials O and M react with each other to effect ALD deposition, but neither reactant gaseous material O nor M reacts with inert gaseous material I. The nomenclature used in FIG. 5 and following suggests some typical types of reactant gases. For example, first reactant gaseous material O could be an oxidizing gaseous material. Second reactant gaseous material M could be an organo-metallic compound. In an alternative embodiment, O may represent a nitrogen- or sulfur-containing gaseous material for forming nitrides and sulfides. Inert gaseous material I could be nitrogen, argon, helium, or other gases commonly used as purge gases in ALD processes. Inert gaseous material I is inert with respect to first or second reactant gaseous materials O and M. Reaction between the first and second reactant gaseous materials would form a metal oxide or other binary compound, such as zinc oxide ZnO, in one embodiment. Reactions between more than two reactant gaseous materials could form other materials such as a ternary compound, for example, ZnAlO.

The cross-sectional views of FIGS. 6A and 6B show, in simplified schematic form, the ALD coating operation performed as substrate 20 passes along output face 36 of delivery head 10 when delivering reactant gaseous materials O and M. In FIG. 6A, the surface of substrate 20 first receives an oxidizing material from output channels 12 designated as delivering first reactant gaseous material O. The surface of the substrate now contains a partially reacted form of material O, which is susceptible to reaction with material M. Then, as substrate 20 passes into the path of the metal compound of second reactant gaseous material M, the reaction with M takes place, forming a metallic oxide or some other thin film material that can be formed from two reactant gaseous materials.

As FIGS. 6A and 6B show, inert gaseous material I is provided in every alternate output channels 12, between the flows of first and second reactant gaseous materials O and M. Sequential output channels 12 are adjacent, that is, share a common boundary, formed by partitions 13 in the embodiments shown. Here, output channels 12 are defined and separated from each other by partitions 13 that extend at a perpendicular to the surface of substrate 20.

As mentioned above, in this particular embodiment, there are no vacuum channels interspersed between the output channels 12, that is, no vacuum (exhaust) channels on either side of a channel delivering gaseous materials to draw out the gaseous materials around the partitions. This advantageous, compact arrangement is possible because of the innovative gas flow that is used. Gas delivery arrays, in one embodiment, can apply substantially vertical (that is, perpendicular) gas flows against the substrate, but then must usually draw off spent gases in the opposite vertical direction, so that exhaust openings and channels would be desirable. A delivery head 10 that directs a gas flow (preferably substantially laminar in one embodiment) along the surface for each reactant and inert gas can more easily handle spent gases and reaction by-products in a different manner, as described subsequently. Thus, in one useful embodiment, the gas flow is directed along and generally parallel to the plane of the substrate surface. In other words, the flow of gases is substantially transverse to the plane of a substrate rather than perpendicular to the substrate being treated.

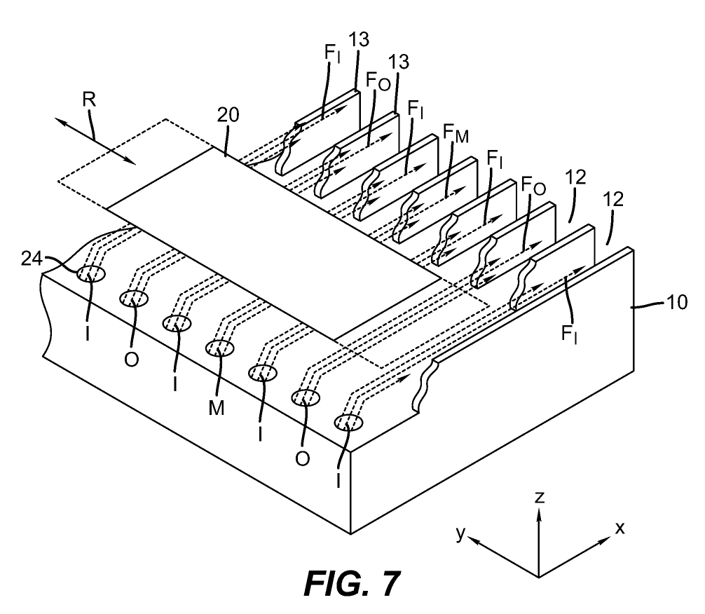

FIG. 7 shows a perspective view of one such embodiment of delivery head 10 that can be used in the present process, from the output face 36 (that is, from the underside with respect to FIGS. 4-6B). Partitions 13 that define and separate the adjacent output channels 12 in this embodiment are represented as partially cut away, to allow better visibility for the gas flows flowing from gas outlet ports 24. FIG. 7 also shows reference x,y,z coordinate axis assignments used in the figures of this disclosure. Output channels 12 are substantially in parallel and extend in a length direction that corresponds to the x coordinate axis. Reciprocating motion of substrate 20, or motion relative to substrate 20, is in the y coordinate direction, using this coordinate assignment.

FIG. 7 shows the gas flows F_{I}, F_{O}, and F_{M} for the various gaseous materials delivered from delivery head 10 with this embodiment. Gas flows F_{I}, F_{O}, and F_{M} are in the x-direction, that is, along the length of elongated output channels 12.

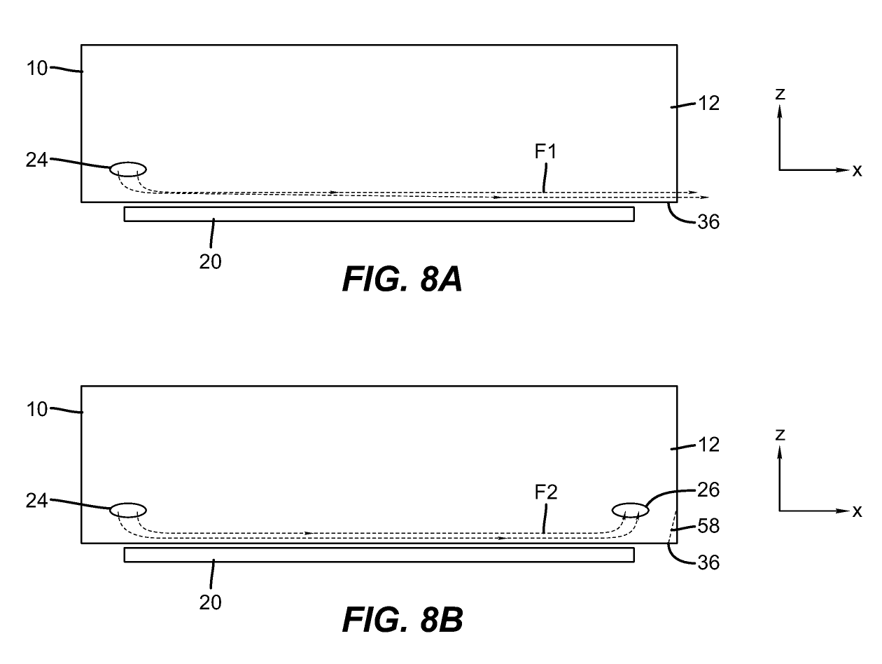

The cross-sectional views of FIGS. 8A and 8B are taken orthogonally to the cross-sections of FIGS. 4-6B and show gas flows in one direction from this view. Within each output channel 12, the corresponding gaseous material flows from a gas output port 24, shown in phantom in the views of FIGS. 8A and 8B. In the embodiment of FIG. 8A, gas flow F1 directs the gaseous material along the length of output channel 12 and across substrate 20, as was described with reference to FIG. 7. Flow F1 continues past the edge of delivery head 10 in this arrangement, flowing outward into the environment or, if desirable, to a gas collection manifold (not shown). FIG. 8B shows an alternative embodiment for gas flow F2 in which output channel 12 also provides an exhaust port 26 for redirection or drawing off of the gas flow. Although unidirectional flows are useful, some degree of mixing can occur and even may be beneficial to some extent, depending on the flow rates and other circumstances involved in a particular application.

A particular delivery head 10 may use output channels 12 configured using any one of the gas flow configurations or combinations thereof, either the F1 flow of FIG. 8A, the F2 flow of FIG. 8B, or some other variation in which gaseous material is directed to flow across substrate 20 along output channel 12, for example in a substantially laminar or smooth fashion with controlled mixing. In one embodiment, one or more exhaust ports 26 are provided for each output channel 12 that delivers a reactant gaseous material. For example, referring to FIG. 7, output channels 12 for first and second reactant gaseous materials, labeled O and M, are configured with exhaust ports 26 to vent or draw off the reactant substances, following the pattern of flow F2 (FIG. 8B). This allows some recycling of materials and prevents undesirable mixing and reaction near the end of the manifold. Output channels 12 for inert gaseous material, labeled I, do not use exhaust ports 26 and thus follow the pattern of flow F1 (FIG. 8A). Although laminar flows are useful in some embodiments, some degree of mixing can occur and even may be beneficial to some extent, depending on the flow rates and other circumstances involved in a particular application.

Exhaust port 26 is not a vacuum port, in the conventional sense, but is simply provided to draw off the gaseous flow in its corresponding output channel 12, thus facilitating a uniform gas flow pattern within the channel. A negative draw, just slightly less than the opposite of the gas pressure at gas output port 24, can help to facilitate an orderly gas flow. The negative draw can, for example, operate at a pressure of between 0.9 and 1.0 atmosphere, whereas a typical vacuum is, for example, below 0.1 atmosphere. An optional baffle 58, as shown in dotted outline in FIG. 8B, may be provided to redirect the flow pattern into exhaust port 26.

Because no gas flow around partition 13 to a vacuum exhaust is needed, output face 36 can be positioned very closely, to within about 1 mil (approximately 0.025 mm) of the substrate surface. By comparison, an earlier approach such as that described in the U.S. Pat. No. 6,821,563 (Yudovsky) required gas flow around the edges of channel sidewalls and was thus limited to 0.5 mm or greater distance to the substrate surface. Positioning the delivery head 10 closer to the substrate surface is desired in the present invention. In one embodiment, distance D from the surface of the substrate can be 0.4 mm or less, or within 0.3 mm, typically within 0.25 mm of the output face of the deposition device or the bottom of the guide walls that provide the flow channels.

In order to provide smooth flow along the length of output channel 12, gas output port 24 may be inclined at an angle away from normal, as indicated in FIGS. 8A and 8B. Optionally, some type of gas flow redirecting structure may also be employed to redirect a downward flow from gas output port 24 so that it forms a gas flow that runs substantially in parallel to output face 36.

As was particularly described with reference to FIGS. 6A and 6B, delivery head 10 requires movement relative to the surface of substrate 20 in order to perform its deposition function. This relative movement can be obtained in a number of ways, including movement of either or both delivery head 10 and substrate 20, such as by movement of a process that provides a substrate support. Movement can be oscillating or reciprocating or could be continuous movement, depending on how many deposition cycles are needed. Rotation of a substrate can also be used, particularly in a batch process, although continuous processes are preferred.

Typically, ALD requires multiple deposition cycles, building up a controlled film depth with each cycle. Using the nomenclature for types of gaseous materials given earlier, a single cycle can, for example in a simple design, provide one application of first reactant gaseous material O and one application of second reactant gaseous material M.

The distance between output channels for O and M reactant gaseous materials determines the needed distance for reciprocating movement to complete each cycle. For an example, delivery head 10, having a nominal channel width of 0.034 inches (0.086 cm) in width W for each output channel 12 and reciprocating motion (along the y axis as used herein) of at least 0.20 inches would be required. For this example, an area of substrate 20 would be exposed to both first reactant gaseous material O and second reactant gaseous material M with movement over this distance. In some cases, consideration for uniformity may require a measure of randomness to the amount of reciprocating motion in each cycle, such as to reduce edge effects or build-up along the extremes of reciprocation travel.

Delivery head 10 may have only enough output channels 12 to provide a single cycle. Alternately, delivery head 10 may have an arrangement of multiple cycles, enabling it to cover a larger deposition area or enabling its reciprocating motion over a distance that allows two or more deposition cycles in one traversal of the reciprocating motion distance.

In one embodiment, a given area of the substrate is exposed to a gas flow in a channel for less than 500 milliseconds, preferably less than 100 milliseconds. For example, the temperature of the substrate during deposition is under 600° C. or typically under 250° C.

For example, in one particular application, it was found that each O-M cycle formed a layer of one atomic diameter over about ¼ of the treated surface. Thus, four cycles, in this case, are needed to form a uniform layer of 1 atomic diameter over the treated surface. Similarly, to form a uniform layer of 10 atomic diameters in this case, then, 40 cycles would be required.

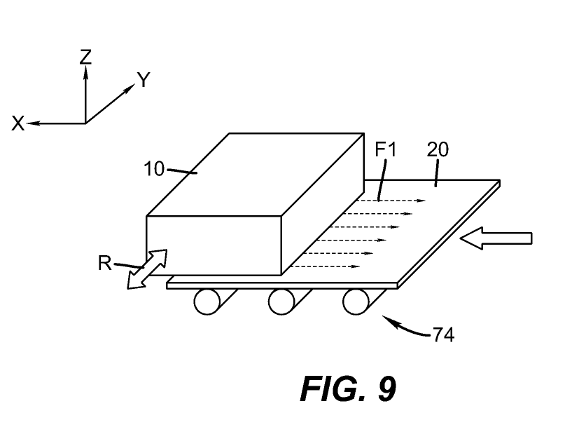

An advantage of the reciprocating motion used for a delivery head 10 used in one embodiment of the present process is that it allows deposition onto a substrate 20 whose area exceeds the area of output face 36. FIG. 9 schematically shows how this broader area coverage can be affected using reciprocating motion along the y axis as shown by arrow R and also movement orthogonal or transverse to the reciprocating motion, relative to the x axis. Again, it must be emphasized that motion in either the x or y direction, as shown in FIG. 9, can be effected either by movement of delivery head 10, or by movement of substrate 20 provided with a substrate support 74 that provides movement, or by movement of both delivery head 10 and substrate 20.

In FIG. 9 the relative motion of the delivery head 10 and the substrate 20 are perpendicular to each other. It is also possible to have this relative motion in parallel. In this case, the relative motion needs to have a nonzero frequency component that represents the oscillation and a zero frequency component that represents the displacement of the substrate 20. This combination can be achieved by: an oscillation combined with displacement of the delivery head 10 over a fixed substrate; an oscillation combined with displacement of the substrate 20 relative to a fixed substrate delivery head 10; or any combinations wherein the oscillation and fixed motion are provided by movements of both the substrate 20 and the delivery head 10.

In one embodiment, ALD can be performed at or near atmospheric pressure and over a broad range of ambient and substrate temperatures, for example at a temperature of under 300° C. Generally, a relatively clean environment is needed to minimize the likelihood of contamination. However, full “clean room” conditions or an inert gas-filled enclosure would not be required for obtaining good performance when using some embodiments of the method of the present invention.

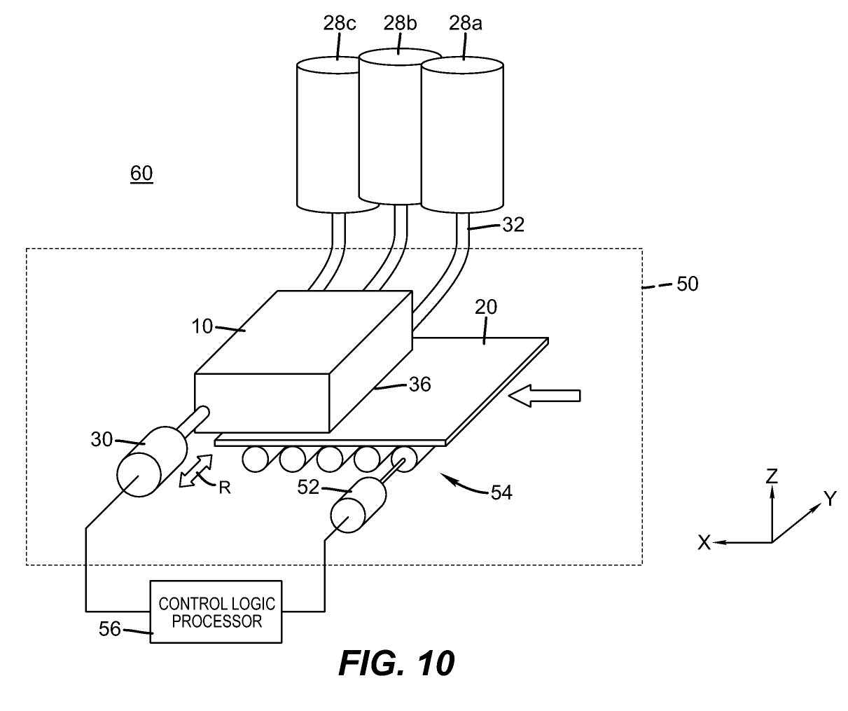

FIG. 10 shows an Atomic Layer Deposition (ALD) 60 process, for making a thin film, having a chamber 50 for providing a relatively well-controlled and contaminant-free environment. Gas supplies 28a, 28b, and 28c provide the first, second, and third gaseous materials to delivery head 10 through supply lines 32. The optional use of flexible supply lines 32 facilitates ease of movement of delivery head 10. For simplicity, an optional vacuum vapor recovery process and other support components are not shown in FIG. 10 but could also be used. A transport subsystem 54 provides a substrate support that conveys substrate 20 along output face 36 of delivery head 10, providing movement in the x direction, using the coordinate axis system employed in the present disclosure. Motion control, as well as overall control of valves and other supporting components, can be provided by a control logic processor 56, such as a computer or dedicated microprocessor assembly, for example. In the arrangement of FIG. 10, control logic processor 56 controls an actuator 30 for providing reciprocating motion to delivery head 10 and also controls a transport motor 52 of transport subsystem 54.

FIG. 11 shows an Atomic Layer Deposition (ALD) system 70 for depositing a thin film in a web arrangement, using a stationary delivery head 10 in which the flow patterns are oriented orthogonally to the configuration of FIG. 10. In this arrangement, motion of web conveyor 62 provides the movement needed for ALD deposition. Reciprocating motion could also be used, such as by repeatedly reversing the direction of rotation of a web roller to move web substrate 66 forward and backwards relative to delivery head 10. Reciprocation motion can also be obtained by allowing a reciprocating motion of the delivery head 10 across an arc whose axis coincides with the roller axis, while the web substrate 66 is moved in a constant motion. In another embodiment at least a portion of delivery head 10 has an output face 36 having an amount of curvature (not shown), which might be advantageous for some web coating applications. Convex or concave curvature could be provided.

Optionally, the method can be accomplished with other apparatus or systems described in more detail in U.S. Pat. Nos. 7,413,982 and 7,456,429 and U.S. Patent Application Publications 2008/0166884 and 2009/0130858 (all noted above and incorporated by reference in their entirety).

In the embodiments in the latter three publications, a delivery device having an output face for providing gaseous materials for thin-film material deposition onto a substrate comprises elongated emissive channels in at least one group of elongated emissive channels, of the three groups of elongated emissive channels (namely, at least one group of: (i) one or more first elongated emissive channels, (ii) one or more second elongated channels, and (iii) a plurality of third elongated channels) that is capable of directing a flow, respectively, of at least one of the first gaseous material, second gaseous material, and the third gaseous material substantially orthogonally with respect to the output face of the delivery device, which flow of gaseous material is capable of being provided, either directly or indirectly from each of the elongated emissive channels in the at least one group, substantially orthogonally to the surface of the substrate.

In one embodiment, apertured plates are disposed substantially in parallel to the output face, and apertures on at least one of the apertured plates form the first, second, and third elongated emissive channels. In an alternative embodiment, the apertured plates are substantially perpendicularly disposed with respect to the output face.

In one such embodiment, the deposition device comprises exhaust channels, for example, a delivery device for thin-film material deposition onto a substrate comprising: (a) a plurality of inlet ports comprising at least a first inlet port, a second inlet port, and a third inlet port capable of receiving a common supply for a first reactive gaseous material, a second reactive gaseous material, and a third (inert purge) gaseous material, respectively, (b) at least one exhaust port capable of receiving exhaust gas from thin-film material deposition and at least two elongated exhaust channels, each of the elongated exhaust channels capable of gaseous fluid communication with the at least one exhaust port, and (c) at least three pluralities of elongated output channels, (i) a first plurality of first elongated output channels, (ii) a second plurality of second elongated output channels, and (iii) a third plurality of third elongated output channels, each of the first, second, and third elongated output channels capable of gaseous fluid communication, respectively, with one of the corresponding first inlet port, second inlet port, and third inlet port; wherein each of the first, second, and third elongated output channels and each of the elongated exhaust channels extend in a length direction substantially in parallel; wherein each first elongated output channel is separated on at least one elongated side thereof from a nearest second elongated output channel by a relatively nearer elongated exhaust channel and a relatively less near third elongated output channel; and wherein each first elongated emissive channel and each second elongated emissive channel is situated between relatively nearer elongated exhaust channels and between relatively less nearer elongated emissive channels.

Further embodiments can comprise a gas diffuser associated with at least one group of the three groups of elongated emissive channels such that at least one of the first, second, and third gaseous material, respectively, is capable of passing through the gas diffuser prior to delivery from the delivery device to the substrate, during thin-film material deposition onto the substrate, and wherein the gas diffuser maintains flow isolation of the at least one of first, second, and third gaseous material downstream from each of the elongated emissive channels in the at least one group of elongated emissive channels.

In one embodiment, such a gas diffuser is capable of providing a friction factor for gaseous material passing there through that is greater than 1×10², thereby providing back pressure and promoting equalization of pressure where the flow of the at least one first, second and third gaseous material exits the delivery device. In one embodiment, the gas diffuser comprises a porous material through which the at least one of the first, second, and third gaseous material passes. In a second embodiment, the gas diffuser comprises a mechanically formed assembly comprising at least two elements comprising interconnected passages, for example, in which nozzles are connected to a flow path provided by a thin space between parallel surface areas in the two elements.

In one embodiment, the one or more of the gas flows from the deposition devices provides a pressure that at least contributes to the separation of the surface of the substrate from the face of the delivery head, thereby providing a “floating head” or “air bearing” type deposition head, which can help to stabilize the gas flows and limit intermixing of the gas flows.

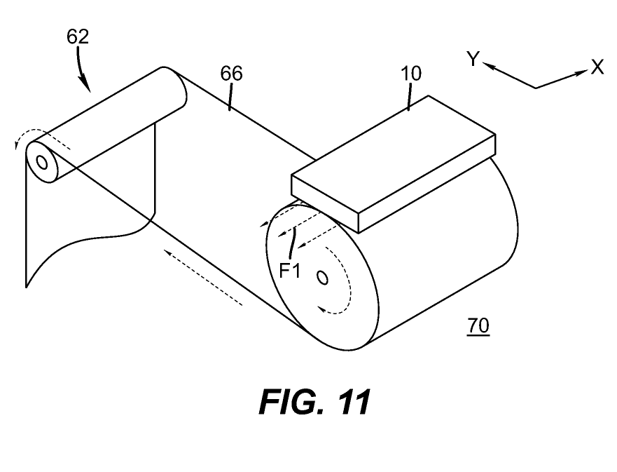

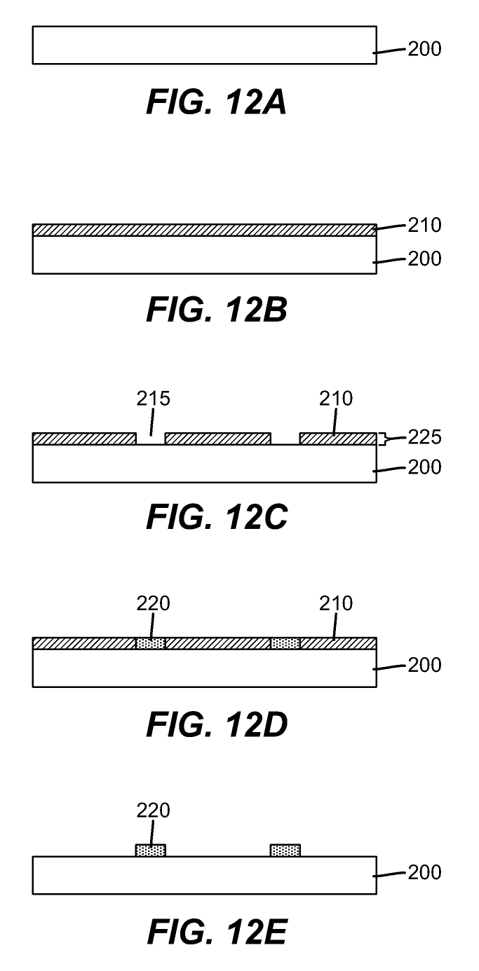

It is the goal to provide a patterned thin film that is not only deposited via an ALD or CVD process, but simultaneously patterned using selective area deposition (SAD) materials and processes. As described above, SAD processes use a deposition inhibitor compound in order to inhibit the ALD growth of the thin film in the non-selected areas. This process can be better understood with reference to FIGS. 12A through 12E. FIG. 12A shows substrate 200 prior to the application of the deposition inhibitor material 210. Although the substrate 200 is illustrated as a bare substrate, one skilled in the art should recognize that substrate 200 might contain layers of materials, either patterned or unpatterned, to serve any purpose electrical, optical, or mechanical, as desired. FIG. 12B shows substrate 200 after a uniform deposition of deposition inhibitor material 210. FIG. 12C illustrates substrate 200 after the step of patterning the deposition inhibitor material 210 into deposition mask 225. The patterning can be done by any method known in the art, including photolithography using either positive or negative acting photoresists, laser ablation, or other subtractive processes. As shown, deposition mask 225 contains areas of deposition inhibitor material 210 and areas of substrate for deposition 215. FIG. 12D illustrates substrate 200 after the step of atomic layer deposition of the desired thin film material. As shown, thin film material 220 is only deposited on the substrate 200 where there was no deposition inhibitor material 210. The thin film material 220 does not form any appreciable thin film over deposition inhibitor material 210. FIG. 12E illustrates a patterned thin film material 220 after removing the deposition inhibitor material 210. It should be understood by one skilled in the art, that in some instances it would not be necessary to remove the deposition inhibitor material 210.

FIGS. 13A, 13C, and 13D should be understood with respect to the descriptions of FIGS. 12A, 12D, and 12E respectively. FIG. 13B illustrates a deposition mask 225 formed by patterned deposition of the deposition inhibitor material 210. Patterned deposition may be done using any additive printing method including, but not limited to inkjet, gravure, flexography, patch coating, screen printing, donor transfer, microcontact printing, or offset lithography.

The present invention provides at least the following embodiments and combinations thereof:

1. A deposition inhibitor composition comprising first and second compatible solvents, the first solvent having a vapor pressure of at least 10 mm Hg at room temperature and the second solvent having a vapor pressure of less than that of the first solvent,

the composition further comprising a hydrophilic deposition inhibitor material that is dissolved in the composition, that is soluble in an aqueous solution that comprises at least 50% by weight of water, and that has a free acid content of less than 2.5 meq/g.

2. The composition of embodiment 1 wherein the second solvent has a vapor pressure that is less than ⅕^{th} of the vapor pressure of the first solvent.

3. The composition of embodiment 1 or 2 wherein the second solvent has a vapor pressure that is less than 1/10^{th} of the vapor pressure of the first solvent.

4. The composition of any of embodiments 1 to 3 wherein the second solvent is soluble in the first solvent at greater than 40% by weight.

5. The composition of any of embodiments 1 to 4 wherein the second solvent is miscible with the first solvent.

6. The composition of any of embodiments 1 to 5 wherein the second solvent is a polyol.

7. The composition of any of embodiments 1 to 6 wherein the second solvent contains one or more carboxy groups.

8. The composition of any of embodiments 1 to 7 wherein the first and second solvents have a molecular weight independently less than 200 g/mol.

9. The composition of any of embodiments 1 to 8 wherein the first solvent is one or more of isopropyl alcohol, water, methanol, ethanol, and acetone.

10. The composition of any of embodiments 1 to 9 wherein the second solvent is one or more of glycerol, 1,3-butanediol, 2,3-butanediol, ethylene glycol, propylene glycol, propanoic acid, and succinic acid.

11. A deposition method for forming a patterned thin film comprising:

A) applying the composition of any of embodiments 1 to 10 comprising a deposition inhibitor material to a substrate,

B) simultaneously or subsequently to step A), patterning the deposition inhibitor material to provide selected areas on the substrate where the deposition inhibitor material is absent, and

C) depositing an inorganic thin film on the substrate by chemical vapor deposition only in those areas where the deposition inhibitor material is absent.

12. The method of embodiment 11 wherein the inorganic thin film is deposited on the substrate by atomic layer deposition.

13. The method of embodiment 11 to 12 wherein the inorganic thin film is either a metal or a metal containing compound.

14. The method of any of embodiments 11 to 13 wherein the deposition inhibitor material has an inhibition power of at least 200 Å during use.

15. The method of any of embodiments 11 to 14 wherein step A is depositing a pattern of the composition comprising the deposition inhibitor material.

16. The method of embodiment 15 wherein the composition comprising the deposition inhibitor material is deposited by inkjet printing, gravure, flexography, donor transfer, micro-contact printing, or offset lithography.

17. An electronic device obtained from the method of any of embodiments 11 to 16, wherein the electronic device is an integrated circuit, active-matrix display, solar cell, active-matrix imager, sensor, or an rf label.

18. A method of treating a substrate comprising:

A) providing the deposition inhibitor composition of any of embodiments 1 to 11 to an application device, and

B) applying the deposition inhibitor composition to a substrate after at least 70% of the first solvent has evaporated.

19. The method of embodiment 18 wherein the application device is a printing plate.

20. The method of embodiment 18 or 19 wherein the application device is a flexographic printing plate.

21. The method of embodiment 18 wherein the application device is an inkjet printing device.

22. The method of embodiment 18 wherein the deposition inhibitor composition is provided to an intermediate substrate and then it is provided to the application device.

23. The method of any of embodiments 18 to 22 wherein the deposition inhibitor composition is provided to the substrate in a patternwise fashion.

The following Examples are provided to illustrate the practice of this invention but they are not meant to be limiting in any manner.

A stock solution S1 was made by combining 8 g of Luviskol K-80 (BASF) and 72 g of isopropyl alcohol. This mixture was stirred for several hours to provide a 10 wt. % solution of Luviskol K-80 in isopropanol.

### COMPARATIVE EXAMPLE 1

An intermediate substrate was produced using a 2.5×2.5 inch (6.35×6.35 cm) piece of glass. A coating solution composed of 1.5 g of solution S1 and 8.5 g of ethanol was made, and 1.5 cm³ of this coating solution was applied to the glass square that was then spun at 2500 rpm for 1 second. After the spin process, the ethanol was allowed to evaporate from the coating in air at room temperature for 1 minute.

An elastomeric flexographic coating plate containing a test pattern was produced by the commercial Kodak Flexcel NX process. A 2 inch (5.1 cm) wide test pattern was mounted to a roller that was 2 inches wide by 2.3 inches (5.1 cm×5.8 cm) in diameter and weighing 950 g.

The roller was inked by rolling it on the above intermediate substrate. No visible change to the intermediate substrate was seen. An attempt to print a pattern was made by rolling the inked roller onto a 2.5 inch (6.35 cm) square piece of silicon. No obvious pattern was transferred, indicating a failed transfer process.

### Invention Example 1

An intermediate substrate was produced using a 2.5×2.5 inch (6.35×6.35 cm) piece of glass. A deposition inhibitor polymer composition composed of 1.5 g of solution S1, 1 g of ethylene glycol, and 7.5 g of ethanol was made. The composition (1.5 cm³) was applied to the glass that was then spun at 2500 rpm for 1 second. After the spin process, the ethanol was allowed to evaporate in air at room temperature for 1 minute. The majority of the ethanol had evaporated but a viscous film of deposition inhibitor material suitable for the printing operation remained on the glass to form the completed intermediate substrate.

The elastomeric plate and roller described in Comparative Example 1 were used. The roller was inked by rolling on the above intermediate substrate. After the inking process, the inverted image of the flexographic pattern was observed in the intermediate substrate, indicating that deposition inhibitor material had been transferred to the roller.

A pattern of deposition inhibitor material was immediately printed by rolling the inked roller onto a 2.5 inch (6.35 cm) square piece of silicon. The transferred pattern of deposition inhibitor material could easily be seen on the silicon. The pattern was dried in air at 180° C. for 30 seconds to cause evaporation of the remaining ethylene glycol solvent. The pattern was still observable on the silicon although more faint.

The patterned substrate was then subjected to ALD growth using a gas bearing ALD coating head as described in U.S. Patent Application Publication 2009/0130858 A1 (Levy). The coating head contained regions for a metal precursor, oxygen precursor gas, and inert purge or separator gases. Zinc oxide films were grown at 200° C. The deposition employed diethyl zinc (DEZ) as the zinc precursor and water as the oxygen precursor. During this deposition, the partial pressure of DEZ in the metal channels was 100 mtorr while the partial pressure of water in the oxygen source channels was 50 mtorr. The inert gas and the carrier gases were nitrogen. The substrate speed yielded a channel residence time (thus ALD exposure time) of 63 msec (the same for all precursor and inert streams). Film growth occurred for 400 ALD cycles. At these conditions, an uninhibited substrate will experience a film growth of about 1.63 Å/cycle.

After film growth, it was observed that minimal or no film growth occurred on regions (the pattern) where the deposition polymer inhibitor had been transferred by the flexographic process, while substantial growth occurred in the areas where the deposition inhibitor material was absent, producing a useful thin film pattern.

### Invention Example 2

The process of Invention Example 1 was repeated except using a deposition inhibitor material composition containing 1.5 g of solution S1, 1 g of 1,3 butanediol, and 7.5 g of ethanol.

The elastomeric plate and roller described in Comparative Example 1 were used. The roller was inked by rolling on the intermediate substrate that was prepared as described in Invention Example 1. After the inking process, the inverted image of the flexographic pattern was observed on the intermediate substrate, indicating that deposition inhibitor material had been transferred to the roller.

A pattern of deposition inhibitor material was immediately printed by rolling the inked roller onto a 2.5 inch (6.35 cm) square piece of silicon. The transferred pattern of deposition inhibitor material could easily be seen on the silicon substrate. The pattern was dried in air at 180° C. for 30 seconds to evaporate the remaining ethylene glycol solvent. The pattern on the silicon was still observable although more faint.

After film growth under the conditions described in Invention Example 1, it was observed that minimal or no film growth occurred on regions (pattern) where the deposition inhibitor material had been transferred by the flexographic process, while substantial growth occurred in the areas in which the deposition inhibitor material was absent, producing a useful thin film pattern.

The invention has been described in detail with particular reference to certain preferred embodiments thereof, but it will be understood that variations and modifications can be effected within the spirit and scope of the invention.

1. A deposition inhibitor composition comprising first and second compatible solvents, the first solvent having a vapor pressure of at least 10 mm Hg at room temperature and the second solvent having a vapor pressure of less than that of the first solvent,
the composition further comprising a hydrophilic deposition inhibitor material that is dissolved in the composition, that is soluble in an aqueous solution that comprises at least 50% by weight of water, and that has a free acid content of less than 2.5 meq/g.

2. The composition of claim 1 wherein the second solvent has a vapor pressure that is less than ⅕^{th} of the vapor pressure of the first solvent.

3. The composition of claim 1 wherein the second solvent has a vapor pressure that is less than 1/10^{th} of the vapor pressure of the first solvent.

4. The composition of claim 1 wherein the second solvent is soluble in the first solvent at greater than 40% by weight.

5. The composition of claim 1 wherein the second solvent is miscible with the first solvent.

6. The composition of claim 1 wherein the second solvent is a polyol.

7. The composition of claim 1 wherein the second solvent contains one or more carboxy groups.

8. The composition of claim 1 wherein the first and second solvents have a molecular weight independently less than 200 g/mol.

9. The composition of claim 1 wherein the first solvent is one or more of isopropyl alcohol, water, methanol, ethanol, and acetone.

10. The composition of claim 1 wherein the second solvent is one or more of glycerol, 1,3-butanediol, 2,3-butanediol, ethylene glycol, propylene glycol, propanoic acid, and succinic acid.

11. A deposition method for forming a patterned thin film comprising:
A) applying the composition of claim 1 comprising a deposition inhibitor material to a substrate,
B) simultaneously or subsequently to step A), patterning the deposition inhibitor material to provide selected areas on the substrate where the deposition inhibitor material is absent, and
C) depositing an inorganic thin film on the substrate by chemical vapor deposition only in those areas where the deposition inhibitor material is absent.

12. The method of claim 11 wherein the inorganic thin film is deposited on the substrate by atomic layer deposition.

13. The method of claim 11 wherein the inorganic thin film is either a metal or a metal containing compound.

14. The method of claim 11 wherein the deposition inhibitor material has an inhibition power of at least 200 Å during use.

15. The method of claim 11 wherein step A is depositing a pattern of the composition comprising the deposition inhibitor material.

16. The method of claim 15 wherein the composition comprising the deposition inhibitor material is deposited by inkjet printing, gravure, flexography, donor transfer, micro-contact printing, or offset lithography.

17. An electronic device obtained from the method of claim 11, wherein the electronic device is an integrated circuit, active-matrix display, solar cell, active-matrix imager, sensor, or an rf label.

18. A method of treating a substrate comprising:
A) providing the deposition inhibitor composition of claim 1 to an application device, and
B) applying the deposition inhibitor composition to a substrate after at least 70% of the first solvent has evaporated.

19. The method of claim 18 wherein the application device is a printing plate.

20. The method of claim 18 wherein the application device is a flexographic printing plate.

21. The method of claim 18 wherein the application device is an inkjet printing device.

22. The method of claim 18 wherein the deposition inhibitor composition is provided to an intermediate substrate and then it is provided to the application device.

23. The method of claim 18 wherein the deposition inhibitor composition is provided to the substrate in a patternwise fashion.
